(19) United States
(12) Patent Application Publication
(10) Pub. No.: US 2015/0055205 A1
(43) Pub. Date: Feb. 26, 2015

(54) MEMS DISPLAY INCORPORATING EXTENDED HEIGHT ACTUATORS

(71) Applicant: Pixtronix, Inc., San Diego, CA (US)

(72) Inventors: Tyler A. Dunn, North Reading, MA (US); Timothy J. Brosnihan, Natick, MA (US)

(73) Assignee: Pixtronix, Inc., San Diego, CA (US)

(21) Appl. No.: 13/973,852

(22) Filed: Aug. 22, 2013

(51) Int. Cl. G02B 26/02; B81C 1/00; B81B 5/00

(52) U.S. Cl. CPC G02B 26/02; B81B 5/00; B81C 1/00634; B81C 2201/0161
USPC 359/230; 359/290; 264/293

(57) ABSTRACT

This disclosure provides systems, methods, and apparatus for a MEMS display incorporating extended height actuators. A light modulating component can be positioned between a substrate and an opposing surface coupled to the substrate. A suspended electrode can be coupled to the light modulating component and suspended between the substrate and the opposing surface. An extended-height electrode can be positioned immediately adjacent to the suspended electrode, and can extend from the substrate up to a height beyond the height of the suspended electrode. The suspended electrode and the extended-height electrode can be configured to move the light modulating component laterally with respect to the substrate.

### TECHNICAL FIELD

This disclosure relates to the field of displays, and in particular, electromechanical systems (EMS) display elements.

### DESCRIPTION OF THE RELATED TECHNOLOGY

Electromechanical systems (EMS) devices include devices having electrical and mechanical elements, such as actuators, optical components (such as mirrors, shutters, and/or optical film layers) and electronics. EMS devices can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of deposited material layers, or that add layers to form electrical and electromechanical devices.

EMS-based display apparatus have been proposed that include display elements that modulate light by selectively moving a light blocking component into and out of an optical path through an aperture defined through a light blocking layer. Doing so selectively passes light from a backlight or reflects light from the ambient or a front light to form an image.

### SUMMARY

The systems, methods and devices of the disclosure each have several innovative aspects, no single one of which is solely responsible for the desirable attributes disclosed herein.

One innovative aspect of the subject matter described in this disclosure can be implemented in an apparatus. The apparatus can include a substrate and an electromechanical systems (EMS) light modulating component positioned between the substrate and an opposing surface coupled to the substrate. The apparatus can also include a suspended electrode coupled to the EMS light modulating component and suspended between the substrate and the opposing surface. The electrostatic actuator can include an extended-height electrode positioned immediately adjacent to the suspended electrode, extending from the substrate up to a height beyond the height of the suspended electrode. The suspended electrode and the extended-height electrode can be configured to move the EMS light modulating component laterally with respect to the substrate.

In some implementations, The EMS light modulating component includes the suspended electrode. The EMS light modulating component can be a microelectromechanical systems (MEMS) shutter. The extended-height electrode can extend from the substrate up to the height of the opposing surface.

In some implementations, the apparatus can include a light blocking layer disposed on the substrate defining a first aperture. The opposing surface can define a second aperture positioned substantially in alignment with the first aperture. The suspended electrode and the extended-height electrode can be configured to move the EMS light modulating component into and out of an optical path through the first and second apertures.

In some implementations, the opposing surface couples to the substrate via an anchor. The anchor coupling the opposing surface to the substrate can support the suspended electrode between the substrate and the opposing surface. In some implementations, the extended-height electrode is electrically isolated from the opposing surface. The extended-height electrode can also include an upper planar portion that is coplanar with portions of the opposing surface.

In some implementations, the apparatus includes a second substrate positioned opposite and spaced apart from the opposing surface relative to the EMS light modulating component. The extended-height electrode can be immediately adjacent to at least the majority length of the first electrode.

In some implementations, the apparatus includes a display and a processor that is configured to communicate with the display. The processor can be configured to process image data. The apparatus can also include a memory device that is configured to communicate with the processor. In some implementations, the apparatus can also include a driver circuit configured to send at least one signal to the display and a controller configured to send at least a portion of the image data to the driver circuit. In some implementations, the apparatus can also include an image source module configured to send the image data to the processor. The image source module can include at least one of a receiver, a transceiver, and a transmitter. In some implementations, the apparatus also includes an input device configured to receive input data and to communicate the input data to the processor.

Another innovative aspect of the subject matter described in this disclosure can be implemented in a method of forming a display apparatus. The method includes fabricating a plurality of display elements on a first mold formed on a substrate. The method includes depositing a first layer of sacrificial material over the fabricated display elements. The method includes patterning the first layer of sacrificial material to create a second mold for portions of a plurality of suspended electrodes and a plurality of extended-height electrodes. The method includes depositing a first layer of structural material over the first layer of sacrificial material such that the deposited first layer of structural material coats the surfaces of the second mold. The method includes patterning the first layer of structural material to define a plurality of apertures through it corresponding to respective display elements to form an elevated aperture layer and to define the plurality of suspended electrodes and the plurality of extended-height electrodes extending from the substrate up to a height beyond the height of the suspended electrodes. The method includes removing the first mold and the first layer of sacrificial material.

In some implementations, patterning the first layer of sacrificial material includes patterning the first layer of sacrificial material to expose portions of a light blocking layer deposited on the substrate on which the plurality of extended-height electrodes can be formed. In some implementations, depositing the layer of structural material over the first layer of sacrificial material includes depositing the structural material such that the deposited structural material is deposited in part on the exposed portions of the light blocking layer. In some implementations, the method includes patterning the layer of structural material such that the plurality of extended-height electrodes are separated from the elevated aperture layer.

In some implementations, a portion of the extended-height electrodes extends in a plane coplanar with the elevated aperture layer and is separated from the elevated aperture layer by a distance in the range of about 3 microns to about 5 microns. In some implementations, the method includes depositing a second layer of structural material over the first mold to form bottom portions of the plurality of extended-height electrodes prior to depositing the first layer of structural material. Depositing the first layer of structural material can include depositing the first layer of structural material over the second layer of structural material.

Another innovative aspect of the subject matter described in this disclosure can be implemented in an apparatus. The apparatus can include a light modulating means suspended between first and second substrates at a height corresponding to a configured-for plane of translational movement. The apparatus can include a first actuation means for applying an attractive electrostatic force to the light modulating means at about the height of the configured-for plane of translational movement. The apparatus can include a second actuation means for applying an attractive electrostatic force to the light modulating means across substantially the entire distance between the first and second substrates. In some implementations, the second actuation means can include a light blocking means for blocking light directed normal to the configured-for plane of translational movement.

Details of one or more implementations of the subject matter described in this specification are set forth in the accompanying drawings and the description below. Although the examples provided in this summary are primarily described in terms of MEMS-based displays, the concepts provided herein may apply to other types of displays, such as liquid crystal displays (LCD), organic light emitting diode (OLED) displays, electrophoretic displays, and field emission displays, as well as to other non-display MEMS devices, such as MEMS microphones, sensors, and optical switches. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1A shows a schematic diagram of an example direct-view microelectromechanical systems (MEMS) based display apparatus.

FIG. 1B shows a block diagram of an example host device.

FIG. 2A shows a top view of an example shutter-based light modulator.

FIG. 2B shows a top view of the example shutter-based light modulator shown in FIG. 2A with an elevated aperture layer removed.

FIG. 2C shows a cross sectional view of the example shutter-based light modulator shown in FIG. 2A.

FIG. 2D shows a second cross sectional view of the example shutter-based light modulator shown in FIG. 2A.

FIG. 3A shows a top view of another example shutter-based light modulator.

FIG. 3B shows a cross sectional view of the example shutter-based light modulator shown in FIG. 3A.

FIG. 3C shows a second cross sectional view of the example shutter-based light modulator shown in FIG. 3A.

FIG. 4 shows flow diagram of an example process for manufacturing a shutter-based light modulator.

FIGS. 5A-5I show cross sectional views of stages of construction of an example display apparatus according to the manufacturing process shown in FIG. 4.

FIG. 6 shows a cross sectional view of a stage of construction of another example display apparatus according to the manufacturing process shown in FIG. 4.

FIG. 7 shows another example process for manufacturing a shutter-based light modulator.

FIGS. 8 and 9 show system block diagrams of an example display device that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (such as e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

In a MEMS display element, display elements can be positioned between a substrate and an elevated aperture layer (EAL). For example, drive electrodes and a shutter can be used to control the passage of light through an aperture in the EAL. The voltage necessary to open and close the shutter can be reduced without substantially reducing the light blocking capabilities of the EAL by incorporating actuator electrodes that extend up from the substrate to a height that is substantially coplanar with the EAL. Alternatively, actuation speeds can be increased at a given voltage level. The upper surface of the actuator electrode can replace portions of the EAL, thereby maintaining the majority of the light blocking surfaces.

Particular implementations of the subject matter described in this disclosure can be implemented to realize one or more of the following potential advantages. In some types of display elements, such as those which include a shutter supported by one or more cantilevered beams, a shutter can be configured to move substantially in a plane perpendicular to a primary face of a drive electrode. Extending the height of the drive electrode can allow for lower power consumption of a display in which the display element is incorporated, relative to the power consumption of displays that do not make use of extended height drive electrodes. The extended height of the drive electrode results in a larger drive electrode surface area. The resulting fringing effects between the drive electrode and the shutter result in a greater force between the drive electrode and the shutter for a given applied voltage, allowing for lower voltage actuation. Alternatively, the same voltage can be applied, resulting in faster actuation

While the shutter may be configured to move substantially in a plane perpendicular to the drive electrode, it can be susceptible to out-of-plane movement. When out-of-plane movement occurs, the force on the shutter caused by the electric field between the drive electrode and the shutter can decrease significantly due to a misalignment between the shutter and the drive electrode. Designing the drive electrode to extend out-of-plane can mitigate this problem. For example, a drive electrode can be configured to extend from a bottom substrate up beyond the shutter. In some implementations, the drive electrode can extend up to an EAL. When a shutter positioned between the bottom substrate and the EAL moves out-of-plane, it will still be aligned with a portion of the drive electrode, due to the extended height of the drive electrode. Therefore, the out-of-plane movement will not result in a significant decrease in force.

In some implementations, as suggested above, the extended height electrodes can extend up to the height of the EAL. Sections of the EAL can be removed to provide space for the extended height electrodes. Upper portions of the extended height electrodes can be designed to extend in a direction coplanar with the EAL. In these implementations, the upper portion of the extended height electrodes can serve to block light that would otherwise escape through the removed sections of the EAL. Therefore, although sections of the EAL are removed, the light blocking capacity of the display element can be maintained.

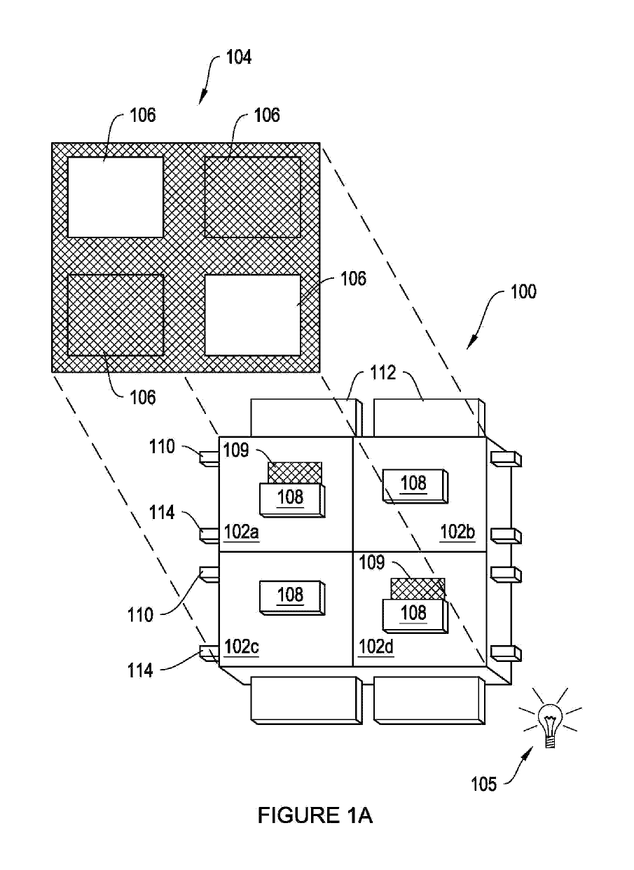

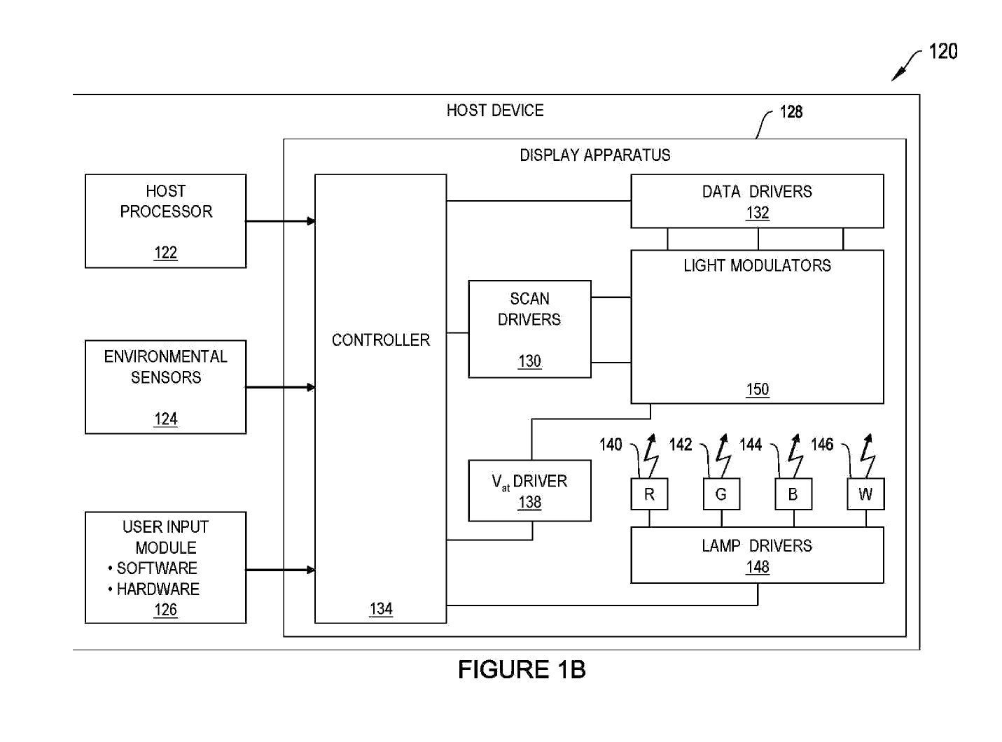

FIG. 1A shows a schematic diagram of an example direct-view MEMS-based display apparatus 100. The display apparatus 100 includes a plurality of light modulators 102a-102d (generally “light modulators 102”) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide luminance level in an image 104. With respect to an image, a “pixel” corresponds to the smallest picture element defined by the resolution of image. With respect to structural components of the display apparatus 100, the term “pixel” refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the user sees the image by looking directly at the display apparatus, which contains the light modulators and optionally a backlight or front light for enhancing brightness and/or contrast seen on the display.

Direct-view displays may operate in either a transmissive or reflective mode. In a transmissive display, the light modulators filter or selectively block light which originates from a lamp or lamps positioned behind the display. The light from the lamps is optionally injected into a lightguide or “backlight” so that each pixel can be uniformly illuminated. Transmissive direct-view displays are often built onto transparent or glass substrates to facilitate a sandwich assembly arrangement where one substrate, containing the light modulators, is positioned directly on top of the backlight.

Each light modulator 102 can include a shutter 108 and an aperture 109. To illuminate a pixel 106 in the image 104, the shutter 108 is positioned such that it allows light to pass through the aperture 109 towards a viewer. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix connected to the substrate and to the light modulators for controlling the movement of the shutters. The control matrix includes a series of electrical interconnects (such as interconnects 110, 112 and 114), including at least one write-enable interconnect 110 (also referred to as a “scan-line interconnect”) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the “write-enabling voltage, V_{WE}”), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate actuation voltages, which are typically higher in magnitude than the data voltages, to the light modulators 102. The application of these actuation voltages then results in the electrostatic driven movement of the shutters 108.

FIG. 1B shows a block diagram of an example host device 120 (i.e., cell phone, smart phone, PDA, MP3 player, tablet, e-reader, netbook, notebook, etc.). The host device 120 includes a display apparatus 128, a host processor 122, environmental sensors 124, a user input module 126, and a power source.

The display apparatus 128 includes a plurality of scan drivers 130 (also referred to as “write enabling voltage sources”), a plurality of data drivers 132 (also referred to as “data voltage sources”), a controller 134, common drivers 138, lamps 140-146, lamp drivers 148 and an array 150 of display elements, such as the light modulators 102 shown in FIG. 1A. The scan drivers 130 apply write enabling voltages to scan-line interconnects 110. The data drivers 132 apply data voltages to the data interconnects 112.

In some implementations of the display apparatus, the data drivers 132 are configured to provide analog data voltages to the array 150 of display elements, especially where the luminance level of the image 104 is to be derived in analog fashion. In analog operation, the light modulators 102 are designed such that when a range of intermediate voltages is applied through the data interconnects 112, there results a range of intermediate open states in the shutters 108 and therefore a range of intermediate illumination states or luminance levels in the image 104. In other cases, the data drivers 132 are configured to apply only a reduced set of 2, 3 or 4 digital voltage levels to the data interconnects 112. These voltage levels are designed to set, in digital fashion, an open state, a closed state, or other discrete state to each of the shutters 108.

The scan drivers 130 and the data drivers 132 are connected to a digital controller circuit 134 (also referred to as the “controller 134”). The controller sends data to the data drivers 132 in a mostly serial fashion, organized in predetermined sequences grouped by rows and by image frames. The data drivers 132 can include series to parallel data converters, level shifting, and for some applications digital to analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 114. In some other implementations, the common drivers 138, following commands from the controller 134, issue voltage pulses or signals to the array 150 of display elements, for instance global actuation pulses which are capable of driving and/or initiating simultaneous actuation of all display elements in multiple rows and columns of the array 150.

All of the drivers (such as scan drivers 130, data drivers 132 and common drivers 138) for different display functions are time-synchronized by the controller 134. Timing commands from the controller coordinate the illumination of red, green and blue and white lamps (140, 142, 144 and 146 respectively) via lamp drivers 148, the write-enabling and sequencing of specific rows within the array 150 of display elements, the output of voltages from the data drivers 132, and the output of voltages that provide for display element actuation. In some implementations, the lamps are light emitting diodes (LEDs).

The controller 134 determines the sequencing or addressing scheme by which each of the shutters 108 can be re-set to the illumination levels appropriate to a new image 104. New images 104 can be set at periodic intervals. For instance, for video displays, the color images 104 or frames of video are refreshed at frequencies ranging from about 10 to 300 Hertz (Hz). In some implementations the setting of an image frame to the array 150 is synchronized with the illumination of the lamps 140, 142, 144 and 146 such that alternate image frames are illuminated with an alternating series of colors, such as red, green, and blue. The image frames for each respective color is referred to as a color subframe. In this method, referred to as the field sequential color method, if the color subframes are alternated at frequencies in excess of 20 Hz, the human brain will average the alternating frame images into the perception of an image having a broad and continuous range of colors. In alternate implementations, four or more lamps with primary colors can be employed in display apparatus 100, employing primaries other than red, green, and blue.

In some implementations, where the display apparatus 100 is designed for the digital switching of shutters 108 between open and closed states, the controller 134 forms an image by the method of time division gray scale, as previously described. In some other implementations, the display apparatus 100 can provide gray scale through the use of multiple shutters 108 per pixel.

In some implementations, the data for an image state 104 is loaded by the controller 134 to the display element array 150 by a sequential addressing of individual rows, also referred to as scan lines. For each row or scan line in the sequence, the scan driver 130 applies a write-enable voltage to the write enable interconnect 110 for that row of the array 150, and subsequently the data driver 132 supplies data voltages, corresponding to desired shutter states, for each column in the selected row. This process repeats until data has been loaded for all rows in the array 150. In some implementations, the sequence of selected rows for data loading is linear, proceeding from top to bottom in the array 150. In some other implementations, the sequence of selected rows is pseudo-randomized, in order to minimize visual artifacts. And in some other implementations the sequencing is organized by blocks, where, for a block, the data for only a certain fraction of the image state 104 is loaded to the array 150, for instance by addressing only every 5^{th} row of the array 150 in sequence.

In some implementations, the process for loading image data to the array 150 is separated in time from the process of actuating the display elements in the array 150. In these implementations, the display element array 150 may include data memory elements for each display element in the array 150 and the control matrix may include a global actuation interconnect for carrying trigger signals, from common driver 138, to initiate simultaneous actuation of shutters 108 according to data stored in the memory elements.

In alternative implementations, the array 150 of display elements and the control matrix that controls the display elements may be arranged in configurations other than rectangular rows and columns. For example, the display elements can be arranged in hexagonal arrays or curvilinear rows and columns. In general, as used herein, the term scan-line shall refer to any plurality of display elements that share a write-enabling interconnect.

In some implementations the functionality of the controller 134 is divided between a microprocessor and a display controller integrated circuit. In some implementations, the display controller integrated circuit is implemented in an integrated circuit logic device, such as an application specific integrated circuit (ASIC). In some implementations, the microprocessor is configured to carry out all or substantially all of the image processing functionality of the controller 134, as well as determining an appropriate output sequence for the display apparatus 128 to use to generate received images. For example, the microprocessor can be configured to convert image frames included in the received image data into a set of image subframes. Each image subframe is associated with a color and a weight, and includes desired states of each of the display elements in the array 150 of display elements. The microprocessor can also be configured to determine the number of image subframes to display to produce a given image frame, the order in which the image subframes are to be displayed, and parameters associated with implementing the appropriate weight for each of the image subframes. These parameters may include, in various implementations, the duration for which each of the respective image subframes is to be illuminated and the intensity of such illumination. These parameters (e.g., the number of subframes, the order and timing of their output, and their weight implementation parameters for each subframe) can be collectively referred to as an “output sequence.”

In contrast, the display controller integrated circuit can be configured primarily to carry out more routine operations of the display apparatus 128. The operations may include retrieving image subframes from a frame buffer and outputting control signals to the scan drivers 130, the data drivers 132, the common drivers 138, and the lamp drivers 148, in response to the retrieved image subframe and the output sequence determined by the microprocessor. The frame buffer can be any volatile or non-volatile integrated circuit memory, such as dynamic random access memory (DRAM), high-speed cache memory, or flash memory. In some other implementations, the display controller integrated circuit causes the frame buffer to output data signals directly to the various drivers 130, 132, 138, and 148.

In some other implementations, the functionality of the microprocessor and the display controller integrated circuit described above are combined into a single logic device such as the controller 134, which may take the form of a microprocessor, an ASIC, a field programmable gate array (FPGA) or other programmable logic device. In some other implementations, the functionality of the microprocessor and the display controller integrated circuit may be divided in other ways between multiple logic devices, including one or more microprocessors, ASICs, FPGAs, digital signal processors (DSPs) or other logic devices.

The host processor 122 generally controls the operations of the host. For example, the host processor 122 may be a general or special purpose processor for controlling a portable electronic device. With respect to the display apparatus 128, included within the host device 120, the host processor 122 outputs image data as well as additional data about the host. Such information may include data from environmental sensors, such as ambient light or temperature; information about the host, including, for example, an operating mode of the host or the amount of power remaining in the host's power source; information about the content of the image data; information about the type of image data; and/or instructions for display apparatus for use in selecting an imaging mode.

As described further below, the host processor 122 can forward instructions to the microprocessor to adjust its output sequence. For example, based on such instructions, the microprocessor can output images using output sequences with fewer or more subframes per color or with a higher or lower frame rate. In addition, based on instructions from the host processor 122, the microprocessor can adjust the relative intensity of each light source (such as red lamp 140, green lamp 142, blue lamp 144, and white lamp 146) in generating each primary color. Doing so adjusts the saturation of each primary color in order for the display apparatus 128 to be able to reproduce various color gamuts or portions of various color gamuts.

The user input module 126 conveys the personal preferences of the user to the controller 134, either directly, or via the host processor 122. In some implementations, the user input module 126 is controlled by software in which the user programs personal preferences such as “deeper color,” “better contrast,” “lower power,” “increased brightness,” “sports,” “live action,” or “animation.” In some other implementations, these preferences are input to the host using hardware, such as a switch or dial. The plurality of data inputs to the controller 134 direct the controller to provide data to the various drivers 130, 132, 138 and 148 which correspond to optimal imaging characteristics.

An environmental sensor module 124 also can be included as part of the host device 120. The environmental sensor module 124 receives data about the ambient environment, such as temperature and or ambient lighting conditions. The sensor module 124 can be programmed to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

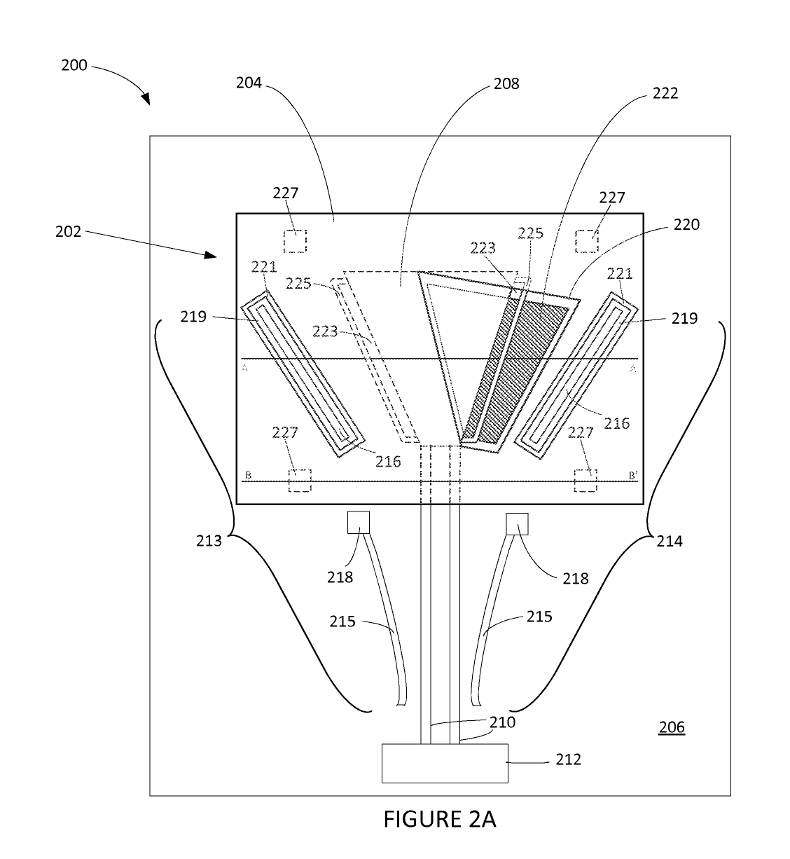

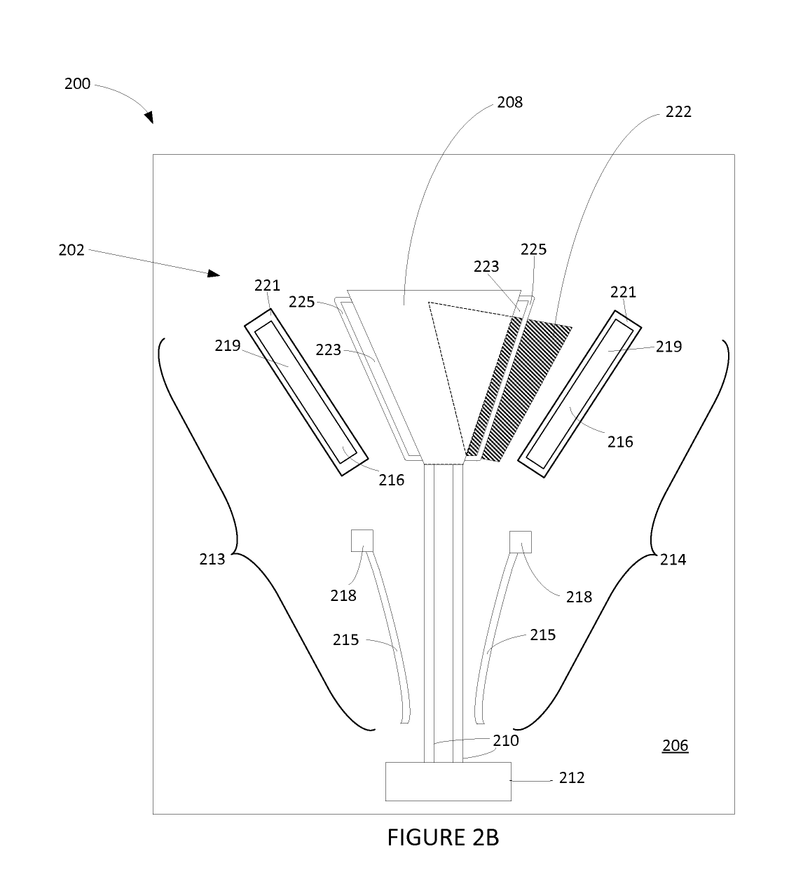

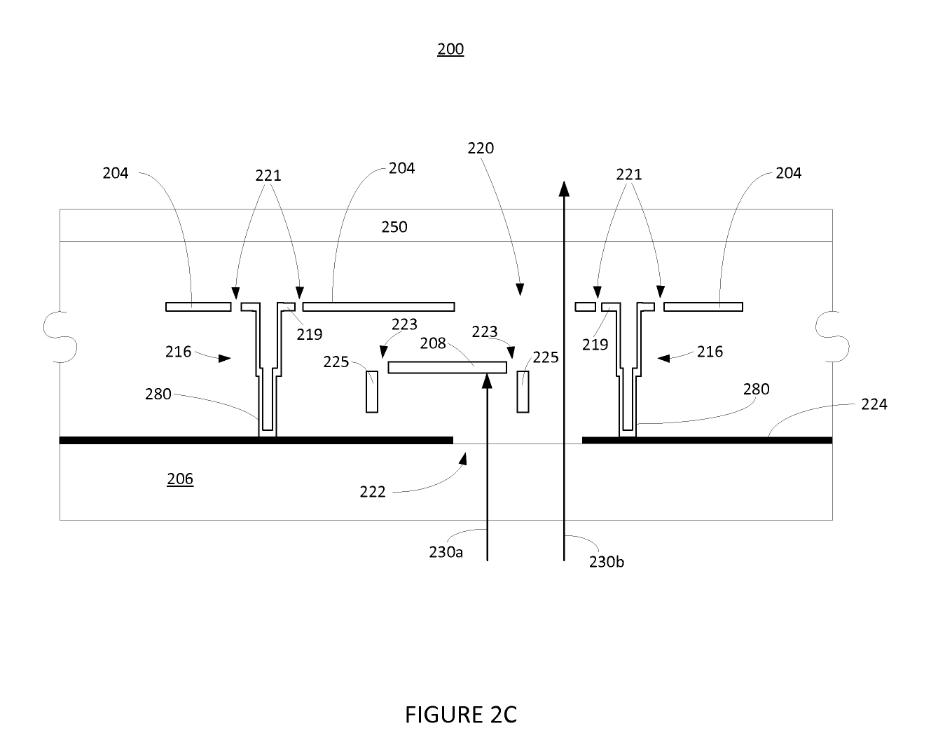

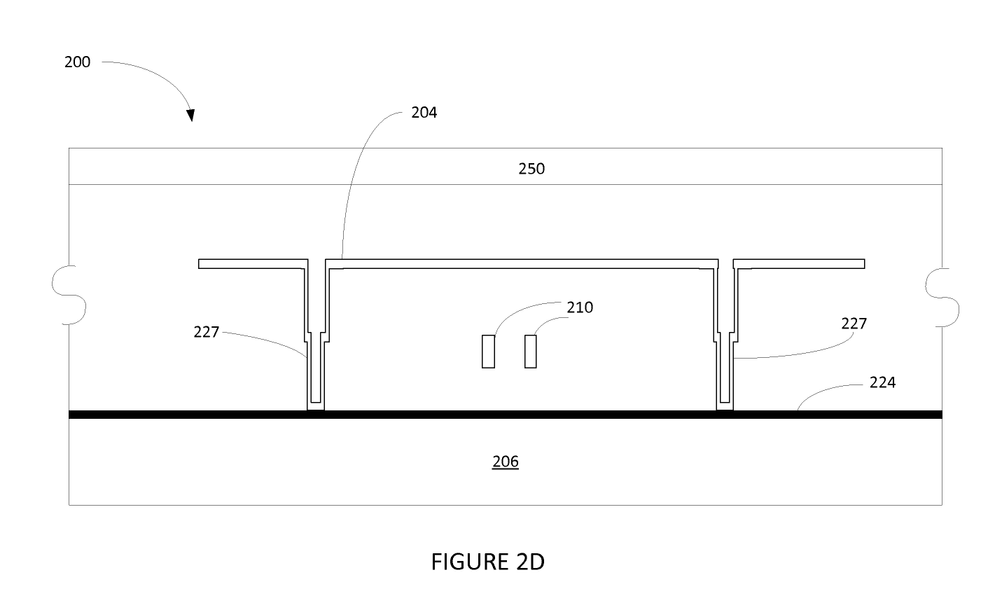

FIG. 2A shows a top view of an example shutter-based light modulator 200. The light modulator 200 includes a shutter assembly 202 built on a lower substrate 206. An EAL 204 is located above the shutter assembly 202. The light modulator 200 also includes a shutter 208 and left and right electrostatic actuators 213 and 214, respectively. The portion of the shutter 208 that is obstructed by the EAL 204 is shown in broken lines in FIG. 2A.

The EAL 204 forms a light blocking layer between the shutter assembly 202 and an opposing substrate of a display in which the shutter-based light modulator 200 is incorporated. The EAL 204 is arranged parallel to the lower substrate 206, and is supported above the lower substrate 206 by anchors 227. The EAL 204 includes a first aperture 220, which is aligned with a second aperture 222 in a light blocking layer disposed on the lower substrate 206. The second aperture 222 is identified by an angled cross-hatching. In the view shown in FIG. 2A, the second aperture 222 is partially obstructed by the shutter 208.

In operation, the shutter-based light modulator 200 can represent a single pixel in an electronic display. The brightness of the pixel represented by the light modulator 200 can be controlled by varying the position of the shutter 208 with respect to the first and second apertures 220 and 222. For example, a backlight positioned beneath the lower substrate 206 can emit light through the second aperture 222. Depending on the position of the shutter 208, the shutter can either block the light passing through the second aperture 222 or allow the light to pass towards the EAL 204. The EAL 204 blocks light that bypasses the shutter 208, such as light passing through the second aperture 222 at a high angle or light reflected or refracted off of the shutter 208 or other surfaces of the shutter based light modulator 200. In some implementations, the EAL 204 can also be light absorbing to help absorb ambient light impinging on it. Light that is allowed to pass by the shutter 208 and through the second aperture 222 can contribute to the formation of an image. Therefore, when the shutter 208 is in a fully light-blocking position, the pixel represented by the light modulator 200 can appear dark, and when the shutter 208 is in a fully transmissive position, the pixel represented by the light modulator 200 can appear bright. Intermediate brightness levels are also possible. For example, as shown in FIG. 2A, the shutter 208 can be placed in a partially transmissive position.

The shutter 208 is a trapezoidal component designed to obstruct light. The narrow end of the shutter 208 is coupled to a first end of a pair of cantilevered beams 210. A second end of the cantilevered beams 210 is coupled to an anchor 212, which is formed over a top surface of the lower substrate 206. The shutter 208 also includes sidewall bumpers 225 on either side which are formed from the same mold defining the cantilevered beams 210.The sidewall bumpers 225 have a primary face that is normal to the substrate and the remainder of the shutter. The sidewall bumpers 225 increase the surface area of the shutter 208 that opposes a pair of extended-height drive electrodes 216 (described further below) included in the shutter assembly 202. The increased surface area results in larger actuation forces when an actuation voltage is applied to the shutter 208. In some other implementations, the shutter 208 can have other shapes. For example, the shutter 208 can be circular, square, rectangular, elliptical, or any other shape. In some implementations, the anchor 212 is configured to support the cantilevered beams 210 and the shutter 208 in a position parallel to the surface of the lower substrate 206.

The cantilevered beams 210 can be configured to bend beginning at about the point at which they are coupled to the anchor 212, so as to move the shutter 208 substantially in a plane that is parallel to the lower substrate 206. For example, the electrostatic actuators 213 and 214 can cause the shutter 208 to move by imparting forces on the shutter 208 and the cantilevered beams 210. The shutter 208 and the cantilevered beams 210 serve as an electrode in each of the two opposing electrostatic actuators 213 and 214. In addition, the electrostatic actuators 213 and 214 each include suspended drive electrodes 215 and extended-height drive electrodes 216.

The suspended drive electrodes 215 are positioned alongside the cantilevered beams 210. Anchors 218 support the suspended drive electrodes 215 and hold the suspended drive electrodes 215 above the lower substrate 206. In some implementations, the suspended drive electrodes 215 are arranged at angles relative to the cantilevered beams 210, such that the distal end of the suspended drive electrode 215 is closer to the cantilevered beams 210 than the proximal end. This configuration allows a lower voltage to initiate the actuation of the actuators 213 and 214. In some implementations, when the electrostatic actuators 213 and 214 are fully actuated, the cantilevered beams 210 come into contact with the suspended drive electrodes 215 along substantially the entire length of the suspended drive electrodes 215. In some implementations, the suspended drive electrodes 215 have substantially the same height as the cantilevered beams 210, and are suspended above the lower substrate 206 at substantially the same distance as the cantilevered beams 210. Such a configuration, which is more clearly illustrated in FIG. 2D, increases the electrostatic force that results from a voltage applied across the suspended drive electrodes 215 and the cantilevered beams 210.

As mentioned above, the electrostatic actuators 213 and 214 also each include extended-height drive electrodes 216. As shown in FIG. 2C, the extended-height drive electrodes 216 include a substantially vertical portion 280 normal to the lower substrate 206 and a horizontal portion 219. The vertical portions 280 extend upwards from the surface of the lower substrate 206 to the height of the EAL 204. In some implementations, the vertical portion 280 extends between about seven microns and about 20 microns above the lower substrate 206. A horizontal portion 219 of each extended-height drive electrode 216 extends outward from the vertical portion 280 in a plane coplanar with the EAL 204. The horizontal portion 219 of each extended-height drive electrode 216 is separated from the EAL 204 by a narrow gap 221. In some implementations, the gap 221 is in the range of about two microns to about four microns. In some implementations, the horizontal portion 219 of the extended-height drive electrodes 216 can have a width in the range of about two microns to about five microns.

FIG. 2B shows a top view of the example shutter-based light modulator 200 shown in FIG. 2A with the EAL 204 and its supporting anchors 227 removed. The entire shutter assembly 202 is visible above the lower substrate 206. The second aperture 222 is partially covered by the shutter 208, as shown by the broken lines outlining the covered portion of the second aperture 222. In some implementations, the second aperture 222 is substantially the same shape as the shutter 208.

The shutter 208 is shown in its relaxed position in FIG. 2B. Both of the electrostatic actuators 213 and 214 are unactuated. The shutter 208 covers a portion of the second aperture 222, while also leaving a portion of the second aperture 222 unobstructed. When the left electrostatic actuator 213 is actuated by application of a voltage across the actuator 213 and the shutter 208, the shutter 208 is pulled towards the actuator 213 into a fully transmissive position. Light passing through the second aperture 222 can therefore exit the display unobstructed by the shutter 208 to contribute to the formation of an image. When the right electrostatic actuator 214 is actuated and the left actuator 213 is unactuated, the shutter is pulled to the right into a fully light obstructing position in which it is substantially aligned over the second aperture 222. In this position, substantially all of the light passing through the second aperture 222 is blocked by the shutter 208.

FIG. 2C shows a cross sectional view of the example shutter-based light modulator 200 shown in FIG. 2A. The cross sectional view of FIG. 2C is taken along the line A-A′ shown in FIG. 2A. A light blocking layer 224 is deposited on a top surface of the lower substrate 206. In some implementations, the lower substrate 206 can be formed from a transparent material. The second aperture 222 is defined by a gap in the light blocking layer 224. The first aperture 220 is aligned above the second aperture 222. An upper substrate 250 is positioned above the EAL 204. In some implementations, the upper substrate 250 forms a coversheet for the display. The upper substrate 250 can be transparent, like the lower substrate 206. The upper substrate 250 and the lower substrate 206 are coupled to one another around their respective perimeters by an epoxy seal.

The shutter 208 is shown in its neutral position (i.e., neither of the actuators 213 and 214 is actuated). The extended-height drive electrodes 216 extend from the lower substrate 206 to the height of the EAL 204. Sidewall bumpers 225 are separated from the body of the shutter 208 by narrow gaps 223. The sidewall bumpers give added surface area to the shutter 208 opposing the vertical portions 280 of the extended-height drive electrodes 216. Voltages applied across either of the extended-height drive electrodes 216 and the shutter 208 cause the shutter 208 to move left or right towards the actuators, as described above. Because movement of the shutter 208 in the direction of the EAL 204 is undesirable, the shutter 208 and the EAL 204 can be maintained at the same voltage. For example, the shutter 208 and the EAL 204 can be electrically coupled to ensure that they remain at the same voltage. Thus, a voltage applied to the shutter 208 (e.g., an actuation voltage), will also be simultaneously applied to the EAL 204.

FIG. 2C also shows two light rays 230a and 230b passing through the second aperture 222. The shutter 208 partially covers the second aperture 222. Therefore, the light ray 230a is unable to escape from the light modulator 200. The light ray 230b, which is not in the path of the shutter 208, passes out of the light modulator 200 through the upper substrate 250. For example, the light rays 230a and 230b can be emitted from a backlight placed below the light modulator 200. Light rays, such as the light ray 230b, that are allowed to pass through the upper substrate 250 can contribute to the formation of an image. The upper substrate 250 can be formed from a transparent material in order to facilitate the transmission of light.

In some implementations, the shutter 208 is configured to move in a plane parallel to both the lower substrate 206 and the EAL 204. However, the shutter 208 can sometimes move out of this plane. In such situations, using only suspended drive electrodes that are aligned with the shutter 208, such as the suspended drive electrodes 215, can result in a significant decrease in actuation force, which can cause slower or incomplete actuation of the shutter 208. The extended-height electrodes 216 can help overcome this problem. Given that the extended-height drive electrodes 216 extend from the lower substrate 206 up to the EAL 204, even if the shutter 208 moves out-of-plane, the sidewall bumpers 225 of the shutter 208 will still remain directly opposite a portion of the extended-height drive electrodes 216. As a result, the shutter 208 will still experience significant actuation force.

FIG. 2D shows a second cross sectional view of the example shutter-based light modulator 200 shown in FIG. 2A. The view shown in FIG. 2D is taken along the line B-B′ as shown in FIG. 2A. In this cross section, the lower substrate 206 is entirely covered by the light blocking layer 224. Accordingly, there is no gap through which light can pass. Cross sections of the cantilevered beams 210 and the anchors 227 are also visible. The anchors 227 extend from the lower substrate 206 to the height of the EAL 204, so that the EAL 204 is suspended above the lower substrate 206. In some implementations, the anchors 227 and the EAL 204 are made from the same material and formed in the same stage of the light modulator's fabrication.

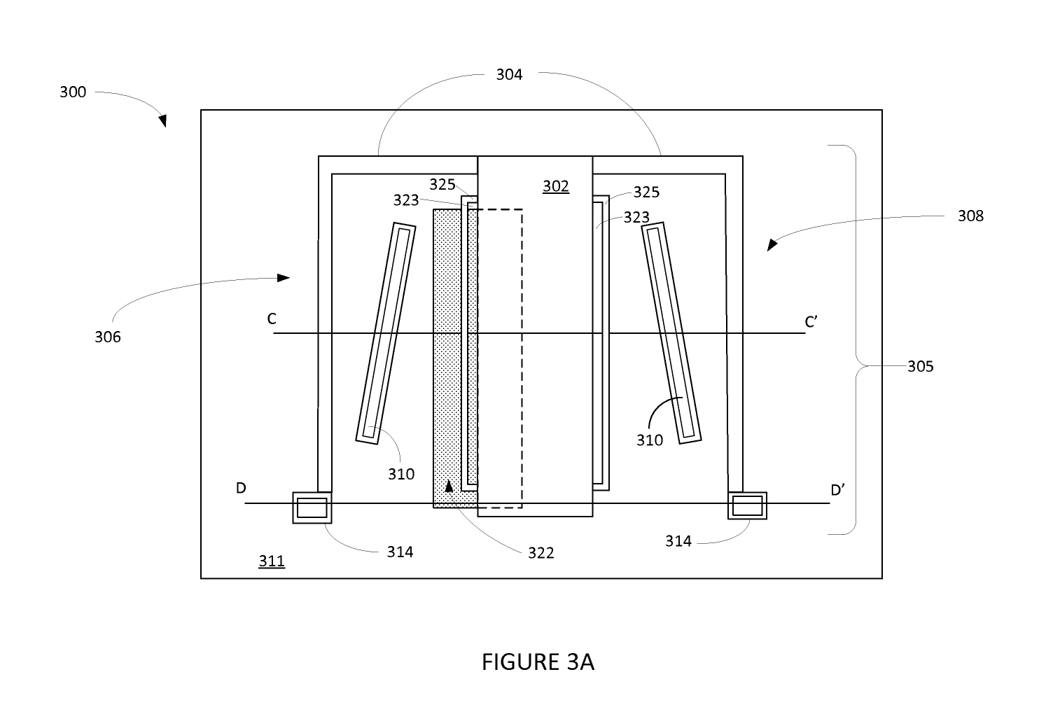

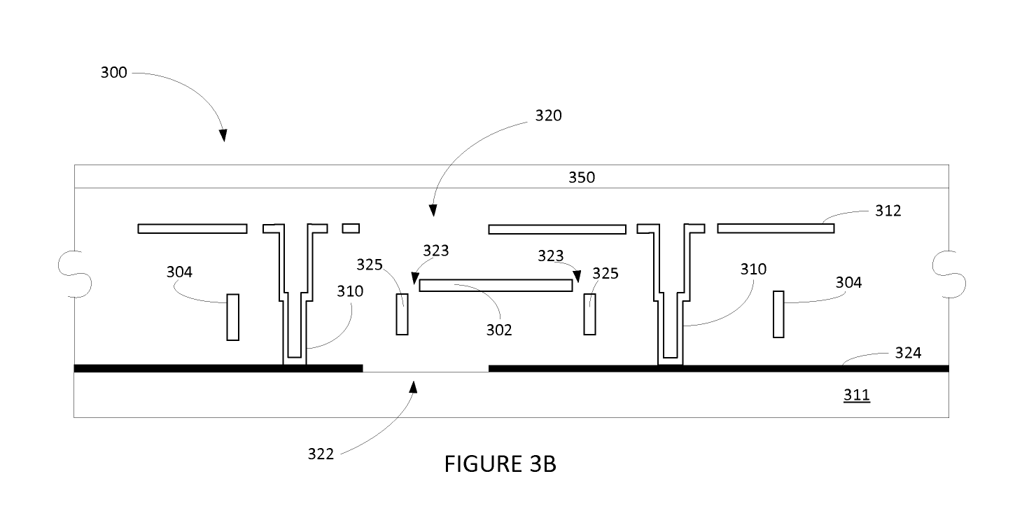

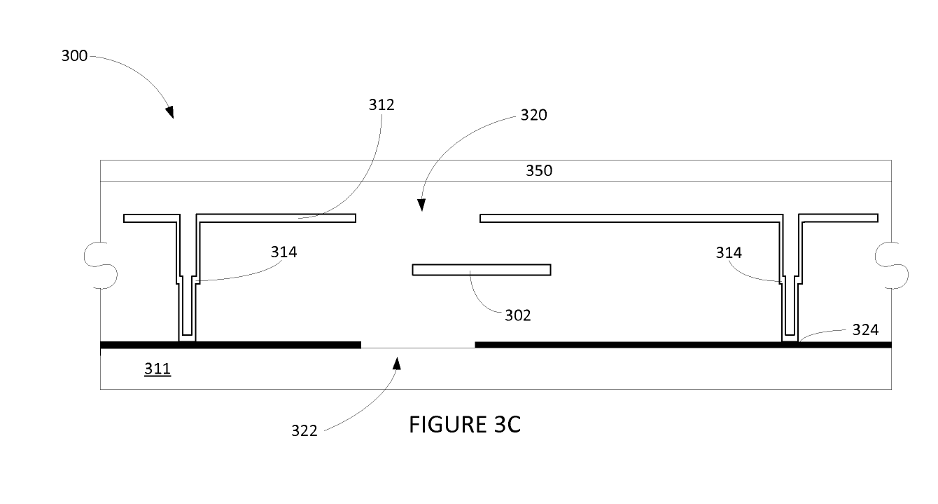

FIG. 3A shows a top view of another example shutter-based light modulator 300. The light modulator 300 includes a shutter 302 coupled to two electrode beams 304. The shutter 302 also includes sidewall bumpers 325, which extend outward from the left and right edges of the shutter 302. Narrow gaps 323 separate each sidewall bumper 325 from a respective edge of the shutter 302. The shutter 302 is part of a shutter assembly 305, which also includes a pair of electrostatic actuators 306 and 308. Each electrostatic actuator 306 and 308 is formed from one of the electrode beams 304 that support the shutter 302 and an extended-height drive electrode 310. The electrode beams 304 are supported above a substrate 311 by anchors 314. In practice, an EAL is positioned above the shutter assembly 305. For illustrative purposes, the EAL is not shown in FIG. 3A. However, it is shown in FIGS. 3B and 3C, which show cross sectional views of the shutter-based light modulator 300.

The operation of the light modulator 300 is substantially similar to the operation of the light modulator 200 shown in FIGS. 2A-2D. For example, a light blocking layer of the substrate 311 includes an aperture 322. The shutter 302 is shown in its neutral position with both of the actuators 306 and 308 unactuated. In this state, the shutter 302 is positioned such that it partially obstructs light passing through the aperture 322. When an actuation voltage is applied to one of the actuators 306 or 308, the corresponding electrode beam 304 is drawn towards the extended-height drive electrode 310. The shutter 302 can therefore be moved into a fully light obstructing state (e.g., by applying a voltage to the actuator 306) or a substantially transmissive state (e.g., by applying a voltage to the actuator 308).

FIG. 3B shows a cross sectional view of the example shutter-based light modulator 300 shown in FIG. 3A. The cross sectional view is taken from the line C-C′ shown in FIG. 3A. A light blocking layer 324 is deposited onto the substrate 311. The light blocking layer 324 defines the first aperture 322. A second aperture 320 is defined by an EAL 312. The shutter 302 is positioned between the first aperture 322 and the second aperture 320. In the unactuated position shown in FIG. 3B, the shutter 302 partially obstructs light passing through the first aperture 322. The sidewall bumpers 325 have a height substantially parallel to the height of the extended-height drive electrodes 310.

Voltages can be applied across the extended-height drive electrodes 310 and the electrode beams 304 in order to vary the position of the shutter 302. The extended height of the extended-height electrodes 310 helps to apply consistent actuation forces even in instances in which the shutter moves out-of-plane. Light passing through the aperture 322 can contribute to the formation of an image after passing through an upper substrate 350. In some implementations, the upper substrate 350 is formed from a transparent material that is fixed at its edges to the substrate 311 via an adhesive, such as an epoxy.

FIG. 3C shows a second cross sectional view of the example shutter-based light modulator 300 shown in FIG. 3A. The cross section is taken along the line D-D′ shown in FIG. 3A. The light blocking layer 324 defining the first aperture 322 is shown atop the substrate 311. The EAL 312 defines the second aperture 320, which is aligned above the first aperture 322. Anchors 314, which are positioned on the top surface of the substrate 311, support the EAL 312. The anchors 314 couple to the electrode beams 304 (not shown in FIG. 3C), which couple to the shutter 302. In this implementations, the anchors 314 electrically couple the EAL 312 to the shutter 302 through the electrode beams 304 in order to maintain the EAL 312 and the shutter 302 at substantially the same voltage.

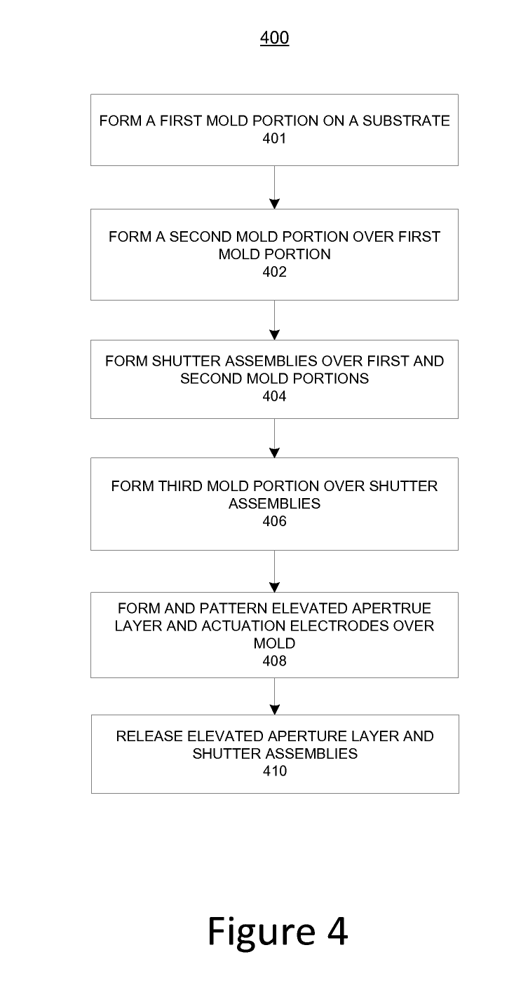

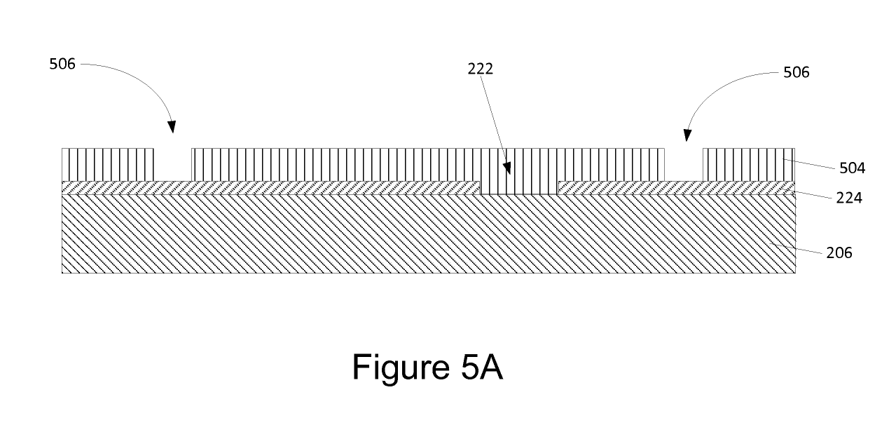

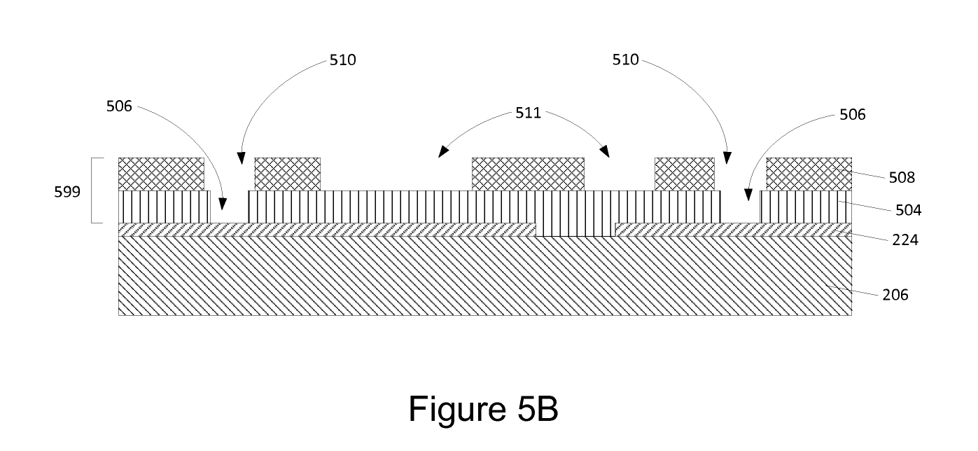

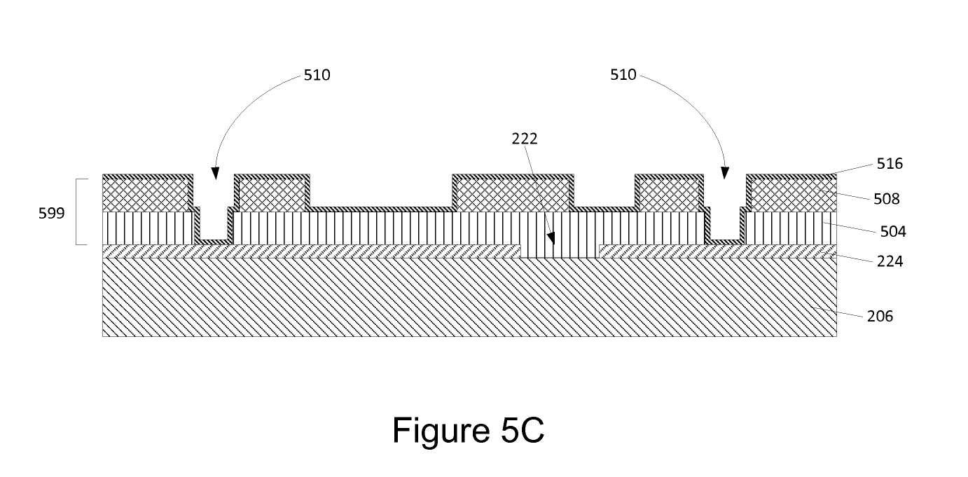

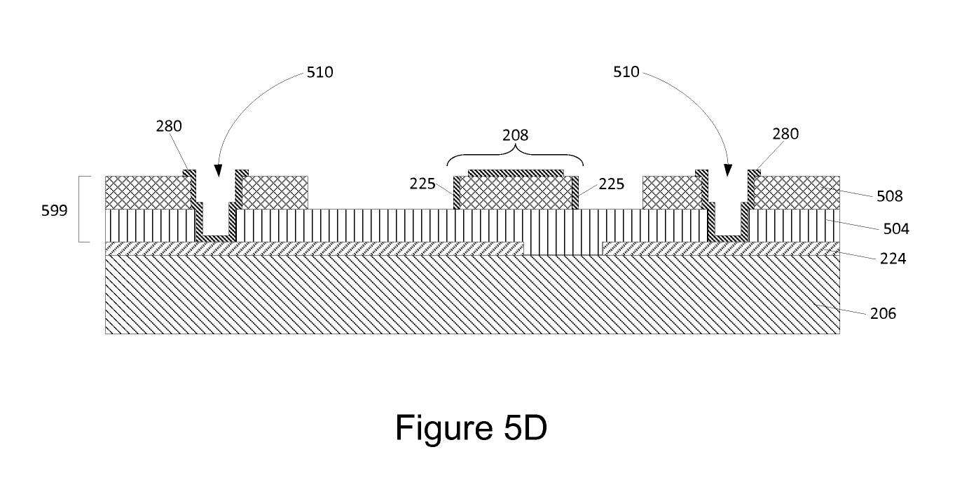

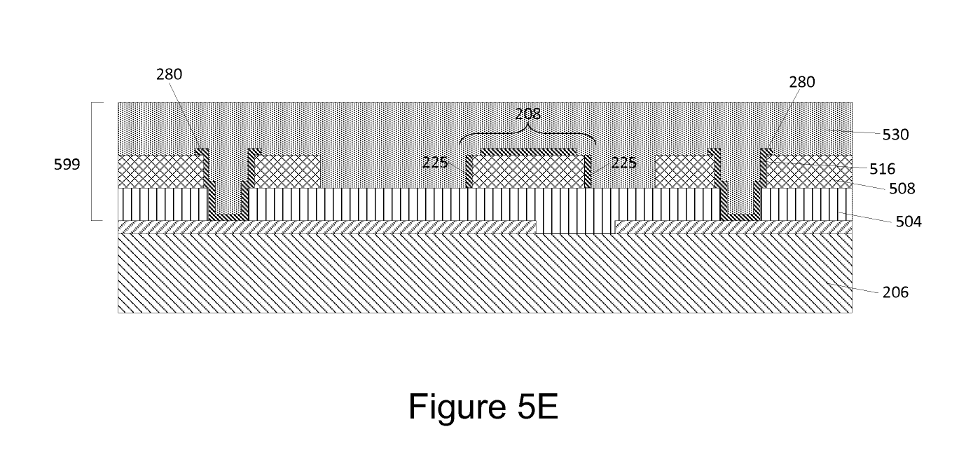

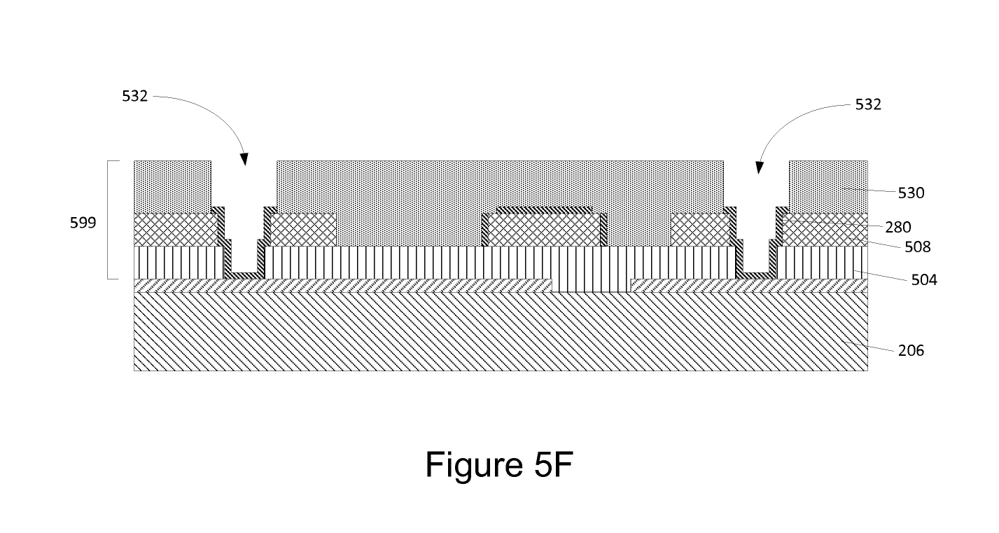

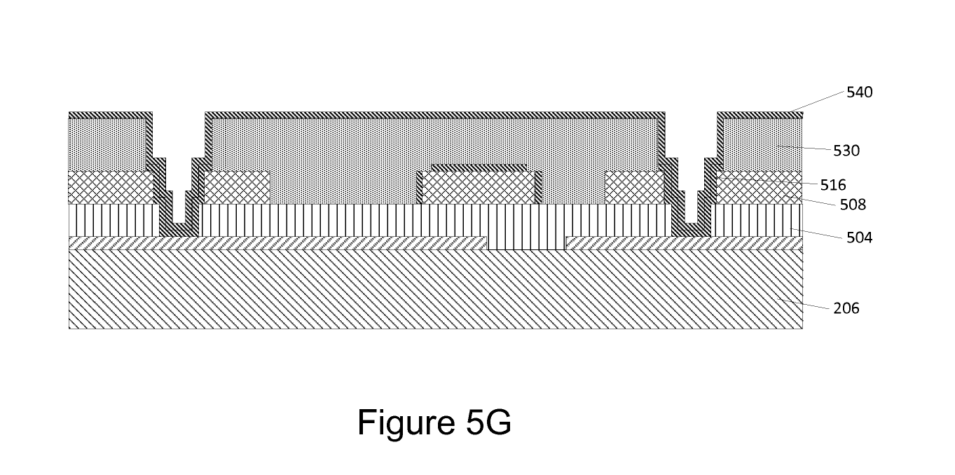

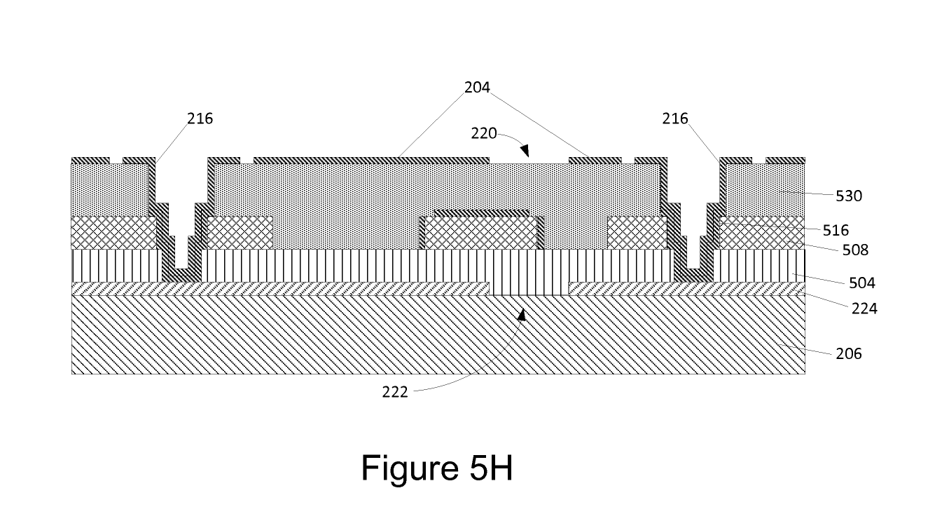

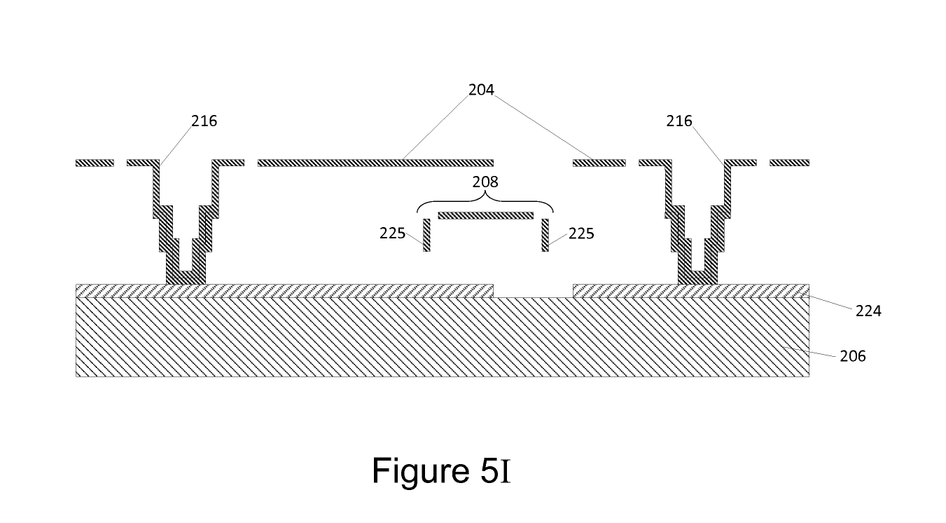

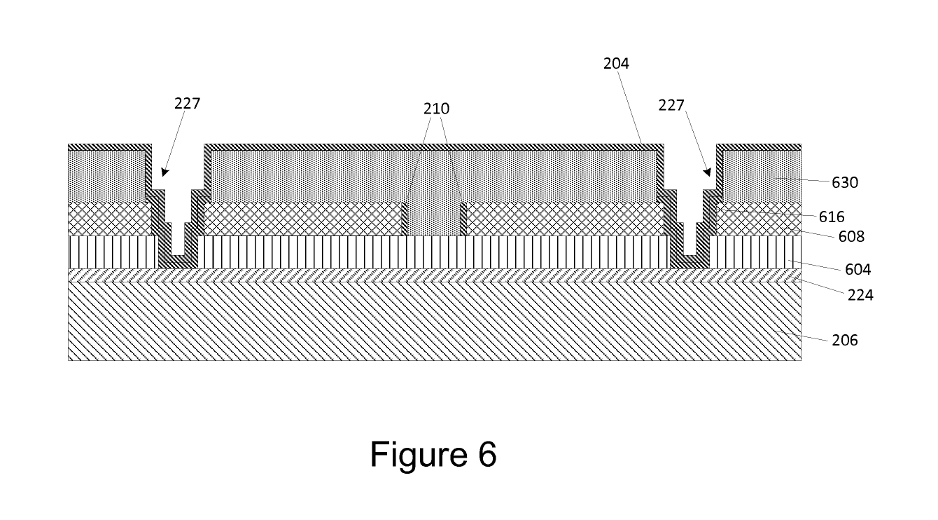

FIG. 4 shows flow diagram of an example process 400 for manufacturing a display apparatus. For example, the process 400 can be used to manufacture the shutter-based light modulator 200 shown in FIG. 2A. In brief overview, the process 400 includes forming a first mold portion on a substrate (stage 401). A second mold portion is formed over the first mold portion (stage 402). Shutter assemblies are then formed using the mold (stage 404). A third mold portion is then formed over the shutter assemblies and the first and second mold portions (stage 406). Next, an EAL and a plurality of actuation electrodes are formed and patterned (stage 408). The shutter assemblies and the EAL are then released (stage 410). Each of these process stages as well as further aspects of the manufacturing process 400 are described below in relation to FIGS. 5A-5I and FIG. 6.

FIGS. 5A-5I show cross-sectional views of stages of construction of an example display apparatus according to the manufacturing process 400 shown in FIG. 4. This process yields a display apparatus formed on a substrate and that includes extended-height electrodes that extend from the surface of the substrate to a surface of an EAL. In the process shown in FIGS. 5A-5I, the display apparatus is formed on a mold made from a sacrificial material. The display apparatus shown in FIGS. 5A-5I is the shutter-based light modulator 200 shown in FIG. 2A. In particular, the cross sectional views of FIGS. 5A-5I are views along the line A-A′ shown in FIG. 2A.

Referring to FIGS. 4 and 5A-5I, the process 400 for forming the shutter-based light modulator 200 begins, as shown in FIG. 5A, with the formation of a first mold portion on top of a substrate (stage 401). The first mold portion is formed by depositing and patterning a first sacrificial material 504 on top of a light blocking layer 224 previously formed on an underlying substrate 206. The first layer of sacrificial material 504 can be or can include polyimide, polyamide, fluoropolymer, benzocyclobutene, polyphenylquinoxylene, parylene, polynorbornene, polyvinyl acetate, polyvinyl ethylene, and phenolic or novolac resins, or any of the other materials identified herein as suitable for use as a sacrificial material. Depending on the material selected for use as the first layer of sacrificial material 504, the first layer of sacrificial material 504 can be patterned using a variety of photolithographic techniques and processes such as by direct photo-patterning (for photosensitive sacrificial materials) or chemical or plasma etching through a mask formed from a photolithographically patterned resist. The pattern defined in the first sacrificial material 504 creates recesses 506 within which the extended-height electrodes will eventually be formed. Additional layers, including layers of material forming a display control matrix may be deposited below the light blocking layer 224 and/or between the light blocking layer 224 and the first sacrificial material 504. The light blocking layer 224 defines a plurality of rear apertures 222. In some implementations, the apertures 505 are formed by a patterning or etching process that takes place prior to the deposition of the sacrificial material 504.

The process of forming the display apparatus continues with forming a second mold portion (stage 402). The second mold portion is formed from depositing and patterning a second sacrificial material 508 on top of the first mold portion formed from the first sacrificial material 504. The second sacrificial material can be the same type of material as the first sacrificial material 504.

FIG. 5B shows the shape of a mold 599, including the first and second mold portions, after the patterning of the second sacrificial material 508. The second sacrificial material 508 has been patterned to form recesses 510 to expose the recesses 506 formed in the first sacrificial material 504. The recesses 510 are wider than the recesses 506 such that a step like structure is formed in the mold 599. The mold 599 also is patterned to form recesses 511. The recesses 511 are formed to provide sidewalls upon which vertical structural features of the shutter 208 such as the sidewall bumpers 225 can be formed, as described further below.

The process of forming the display apparatus 400 continues with the formation of shutter assemblies using the mold 599 (stage 404), as shown in FIGS. 5C and 5D. The shutter assemblies are formed by depositing structural material 516 onto the exposed surfaces of the mold 599, as shown in FIG. 5C, followed by patterning the structural material 516, resulting in structure shown in FIG. 5D. In some implementations, the structural material 516 is deposited in a chemical vapor deposition (CVD) process or a plasma-enhanced CVD (PECVD) process. The structural material 516 can include one or more layers including mechanical as well conductive layers. Suitable structural materials 516 include metals such as aluminum (Al), copper (Cu), nickel (Ni), chromium (Cr), molybdenum (Mo), titanium (Ti), tantalum (Ta), niobium (Nb), neodymium (Nd), or alloys thereof; dielectric materials such as aluminum oxide (Al₂O₃), silicon oxide (SiO₂), tantalum pentoxide (Ta₂O₅), or silicon nitride (Si₃N₄); or semiconducting materials such as diamond-like carbon, Si, Ge, GaAs, CdTe or alloys thereof. In some implementations, the structural material 516 includes a stack of materials. For example, a layer of conductive structural material may be deposited between two non-conductive layers. In some implementations, a non-conductive layer is deposited between two conductive layers. In some implementations, such a “sandwich” structure helps to ensure that stresses remaining after deposition and/or stresses that are imposed by temperature variations will not cause bending, warping or other deformation of the structural material 516. The structural material 516 is deposited to a thickness of between about 0.5 microns and about two microns. In some implementations, the structural material 516 is deposited to have a thickness of less than about 1.5 microns.

After deposition, the structural material 516 (which may be a composite of several materials as described above) is patterned, as shown in FIG. 5D. First, a photoresist mask is deposited on the structural material 516. The photoresist is then patterned. The pattern developed into the photoresist is designed such that, after a subsequent etch stage, the remaining structural material 516 forms a shutter 208 with sidewall bumpers 225 and the bottom portions 280 of extended-height electrodes 216. To create the sidewall bumpers 225, the photoresist may be patterned to remove the photoresist in regions on either side of the sidewalls that form the edge of the recess 511. Doing so helps ensure no extraneous shutter material remains at the bottom of the recess 511. Given the resolution of the patterning process, achieving this goal only by removing photoresist covering the bottom of the recess 511 often yields an imperfect result. In the cross sectional view shown in FIG. 5D, the sidewall bumpers 225 are separated from the shutter 208 by a narrow gap. The etch of the structural material 516 can be an isotropic etch, an anisotropic etch and can carried out in a plasma atmosphere with a voltage bias applied to the substrate, or to an electrode in proximity to the substrate, or a combination of isotropic and anisotropic etches.

Once the shutter assemblies of the display apparatus are formed (stage 404), the manufacturing process 400 continues with forming and patterning the EAL of the display. The process of forming the EAL begins with the formation of a third mold portion on top of the shutter assemblies (stage 406). The third mold portion is formed from a third sacrificial material layer 530. The third sacrificial material layer 530 can be or include any of the sacrificial materials disclosed herein. FIG. 5E shows the shape of the mold 599 (including the first, second, and third mold portions) that is created after depositing the third sacrificial material layer 530. FIG. 5F shows the shape of the mold 599 that is created after patterning the third sacrificial material layer 530. In particular, the mold 599 shown in FIG. 5F includes recesses 532 where upper portions of the extended-height electrodes 216 will be formed.

The EAL 204 and a plurality of actuation electrodes are then formed, as shown in FIGS. 5G and 5H (stage 408). First one or more layers of aperture layer material 540 are deposited on the mold 599. In some implementations, the aperture layer material can be or can include one or more layers of a conductive material, such as a metal or conductive oxide, or a semiconductor. In some implementations, the aperture layer can be made of or can include a polymer that is non-conductive. Some examples of suitable materials were provided above with respect to FIG. 5C. In some implementations, the aperture layer material 540 has a thickness of less than about two microns.

Stage 408 continues with etching the deposited aperture layer material 540 (shown in FIG. 5G), resulting in an EAL 204, as shown in FIG. 5H. The etch of the aperture layer material 540 can be an anisotropic etch, an isotropic etch, or a combination of anisotropic and isotropic etches. In some implementations, the application of the anisotropic etch is performed in a manner similar to the anisotropic etch described with respect to FIG. 5D. In some other implementations, depending on the type of material used to form the aperture layer, the aperture layer may be patterned and etched using other techniques. Upon applying the etch, an aperture layer aperture 220 is formed in a portion of the EAL 204 aligned with an aperture 222 formed through the light blocking layer 224. The etch also results in the separation of the extended-height electrodes 216 from the EAL 204, such that the electrodes 216 and the EAL 204 are electrically isolated. For example, the extended-height electrodes 216 can be separated from the EAL 204 by a distance in the range of about two microns to about five microns. The extended-height electrodes 216 are formed from the aperture layer material 540 as well as the structural material 516 deposited in stage 404.

The mold 599 is then removed (stage 410). The result, shown in FIG. 5I, includes the extended-height electrodes 216 spanning the distance between the substrate 206 and the EAL 204. The shutter 208 is positioned between the substrate 206 and the EAL 204. In some implementations, the mold is removed using standard MEMS release methodologies, including, for example, exposing the mold to an oxygen plasma, wet chemical etching, or vapor phase etching.

FIG. 6 shows another cross sectional view of a stage of construction of an example display apparatus according to the manufacturing process shown in FIG. 4. In particular, the view shown in FIG. 6 corresponds to the view along the cross sectional line B-B′ shown in FIG. 2A. The display apparatus is shown in FIG. 6 in its state immediately prior to the removal of the mold on which it is formed. For example, the state of fabrication shown in FIG. 6 is the same as the state shown in FIG. 5H. The substrate 206 and light blocking layer 224 are shown. The aperture in the light blocking layer 224 is not visible in the cross sectional view of FIG. 6. The first and second layers of sacrificial material 604 and 608 were deposited and patterned in a manner that left recesses in which lower portions of the anchors 227 were formed. The second layer of sacrificial material 608 was also patterned to form a recess that served as a mold for the two cantilevered beams 210. Structural material 616 was then deposited and allowed to fill the recesses in the molds. The cantilevered beams 210 and the two anchors 227 were formed by patterning the layer of structural material 616 (shown in FIG. 5C) deposited on top of the second layer of sacrificial material 608. The EAL was formed from another layer of structural material deposited over a third layer of sacrificial material. The EAL 204 is continuous with the anchors 227, so that the anchors 227 support the EAL 204 above the other components of the display apparatus in its final configuration.

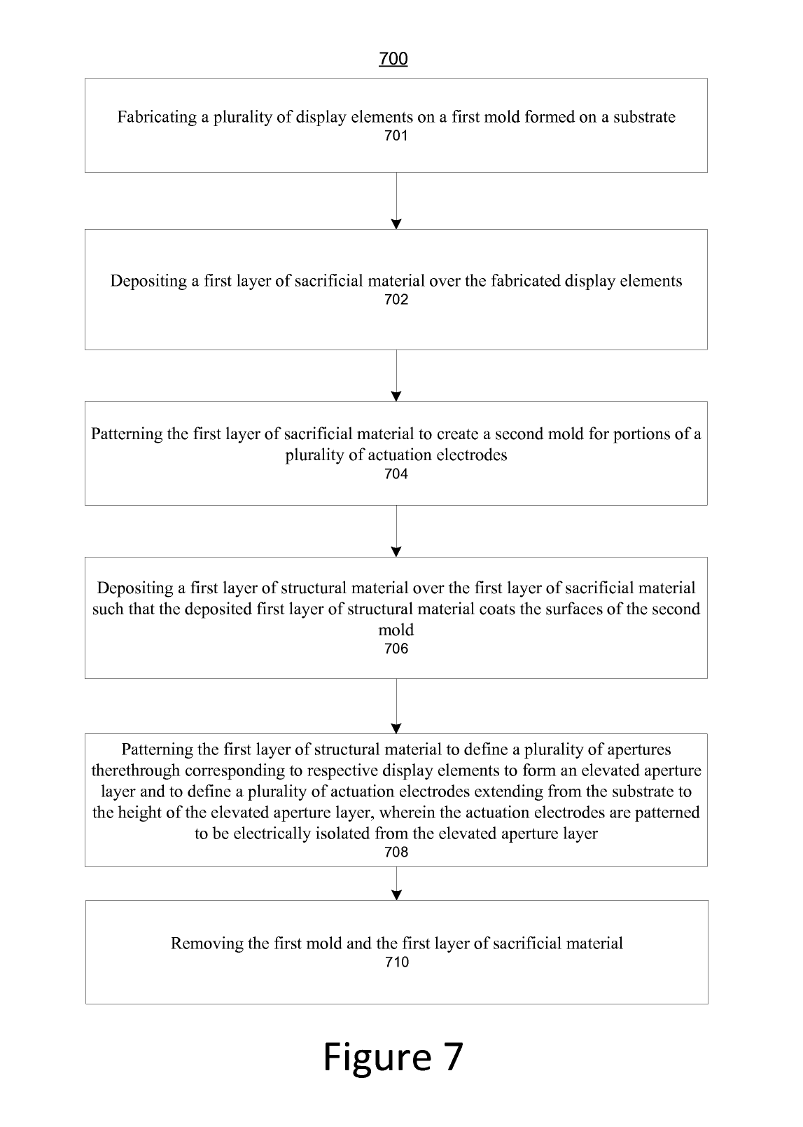

FIG. 7 shows another example process 700 for manufacturing a shutter-based light modulator. The process 700 can be considered another representation of the manufacturing process 400 shown in FIG. 4. The process 700 includes fabricating a plurality of display elements on a first mold formed on a substrate (stage 701). The process 700 includes depositing a first layer of sacrificial material over the fabricated display elements (stage 702) and patterning the first layer of sacrificial material to create a second mold for portions of a plurality of actuation electrodes (stage 704). The process 700 includes depositing a first layer of structural material over the first layer of sacrificial material such that the deposited first layer of structural material coats the surfaces of the second mold (stage 706). The process 700 includes patterning the first layer of structural material to define a plurality of apertures therethrough corresponding to respective display elements to form an elevated aperture layer and to define a plurality of actuation electrodes extending from the substrate to the height of the elevated aperture layer, wherein the actuation electrodes are patterned to be electrically isolated from the elevated aperture layer (stage 708). The process 700 also includes removing the first mold and the first layer of sacrificial material (stage 710). Stage 710 of the process 700 corresponds to stage 410 of the process 400.

The stages of the process 700 are similar to the stages of the process 400 shown in FIG. 4. For example, stage 701 of the process 700 corresponds to stages 401, 402, and 404 of the process 400. Stages 702 and 704 of the process 700 correspond to stage 406 of the process 400. Stages 706 and 708 of the process 700 correspond to stage 408 of the process 400. Stage 710 of the process 700 corresponds to stage 410 of the process 400.

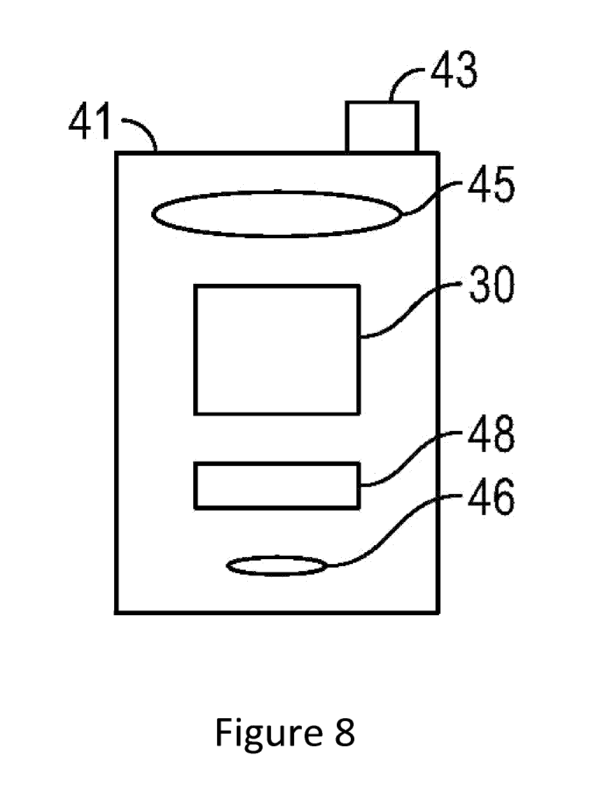

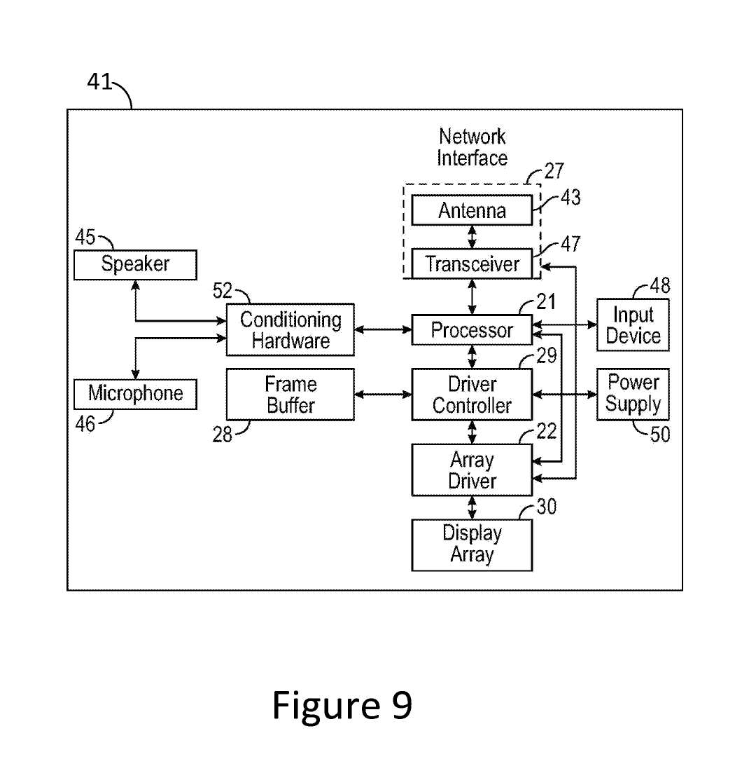

FIGS. 8 and 9 show system block diagrams of an example display device 40 that includes a plurality of display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display. The display 30 also can include a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 30 can include a mechanical light modulator-based display, as described herein.

The components of the display device 40 are schematically illustrated in FIG. 8. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be capable of conditioning a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIGS. 8 and 9, can be capable of functioning as a memory device and communicating with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11 a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements. In some implementations, the array driver 22 and the display array 30 are a part of a display module. In some implementations, the driver controller 29, the array driver 22, and the display array 30 are a part of the display module.

In some implementations, the driver controller 29, the array driver 22, and the display array 30 are appropriate for any of the types of displays described herein. For example, the driver controller 29 can be a conventional display controller or a bi-stable display controller (such as a mechanical light modulator display element controller). Additionally, the array driver 22 can be a conventional driver or a bi-stable display driver (such as a mechanical light modulator display element controller). Moreover, the display array 30 can be a conventional display array or a bi-stable display array (such as a display including an array of mechanical light modulator display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be capable of allowing, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be capable of acting as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be capable of receiving power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising:
a substrate;
an electromechanical systems (EMS) light modulating component positioned between the substrate and an opposing surface coupled to the substrate;
a suspended electrode coupled to the EMS light modulating component and suspended between the substrate and the opposing surface; and
an extended-height electrode positioned immediately adjacent to the suspended electrode, extending from the substrate up to a height beyond the height of the suspended electrode;
wherein the suspended electrode and the extended-height electrode are configured to move the EMS light modulating component laterally with respect to the substrate.

2. The apparatus of claim 1, wherein the EMS light modulating component is a microelectromechanical systems (MEMS) shutter.

3. The apparatus of claim 1, wherein the extended-height electrode extends from the substrate up to the height of the opposing surface.

4. The apparatus of claim 1, comprising a light blocking layer disposed on the substrate defining a first aperture, wherein the opposing surface defines a second aperture positioned substantially in alignment with the first aperture, and the suspended electrode and the extended-height electrode are configured to move the EMS light modulating component into and out of an optical path through the first and second apertures.

5. The apparatus of claim 5, wherein the opposing surface couples to the substrate via an anchor.

6. The apparatus of claim 6, wherein the anchor coupling the opposing surface to the substrate supports the suspended electrode between the substrate and the opposing surface.

7. The apparatus of claim 7, wherein the extended-height electrode is electrically isolated from the opposing surface.

8. The apparatus of claim 1, wherein the extended-height electrode includes an upper planar portion that is coplanar with portions of the opposing surface.

9. The apparatus of claim 1, comprising a second substrate positioned opposite and spaced apart from the opposing surface relative to the EMS light modulating component.

10. The apparatus of claim 1, wherein the extended-height electrode is immediately adjacent to at least the majority length of the suspended electrode.

11. The apparatus of claim 1, further comprising:
a display;
a processor that is configured to communicate with the display, the processor being configured to process image data; and
a memory device that is configured to communicate with the processor.

12. The apparatus of claim 11, further comprising:
a driver circuit configured to send at least one signal to the display; and
a controller configured to send at least a portion of the image data to the driver circuit.

13. The apparatus of claim 11, further comprising:
an image source module configured to send the image data to the processor, wherein the image source module comprises at least one of a receiver, transceiver, and transmitter.

14. The apparatus of claim 11, further comprising:
an input device configured to receive input data and to communicate the input data to the processor.

15. A method of forming a display apparatus, comprising:
fabricating a plurality of display elements on a first mold formed on a substrate;
depositing a first layer of sacrificial material over the fabricated display elements;
patterning the first layer of sacrificial material to create a second mold for portions of a plurality of suspended electrodes and a plurality of extended-height electrodes;
depositing a first layer of structural material over the first layer of sacrificial material such that the deposited first layer of structural material coats the surfaces of the second mold;
patterning the first layer of structural material to define:
a plurality of apertures in the first layer of structural material corresponding to respective display elements to form an elevated aperture layer;
the plurality of suspended electrodes; and
the plurality of extended-height electrodes extending from the substrate up to a height beyond the height of the suspended electrodes; and
removing the first mold and the first layer of sacrificial material.

16. The method of claim 15, wherein patterning the first layer of sacrificial material further includes patterning the first layer of sacrificial material to expose portions of a light blocking layer deposited on the substrate on which the plurality of extended-height electrodes can be formed.

17. The method of claim 16, wherein depositing the layer of structural material over the first layer of sacrificial material further includes depositing the structural material such that the deposited structural material is deposited in part on the exposed portions of the light blocking layer.

18. The method of claim 17, further comprising:
patterning the layer of structural material such that the plurality of extended-height electrodes are separated from the elevated aperture layer.

19. The method of claim 15, wherein a portion of the extended-height electrodes extends in a plane coplanar with the elevated aperture layer and is separated from the elevated aperture layer by a distance in the range of about 3 microns to about 5 microns.

20. The method of claim 15, further comprising:
prior to depositing the first layer of structural material, depositing a second layer of structural material over the first mold to form bottom portions of the plurality of extended-height electrodes, wherein depositing the first layer of structural material comprises depositing the first layer of structural material over the second layer of structural material.

21. An apparatus comprising:
a light modulating means suspended between first and second substrates at a height corresponding to a configured-for plane of translational movement;
a first actuation means for applying an attractive electrostatic force to the light modulating means at about the height of the configured-for plane of translational movement;
a second actuation means for applying an attractive electrostatic force to the light modulating means across substantially the entire distance between the first and second substrates.

22. The apparatus of claim 21, wherein the second actuation means includes a light blocking means for blocking light directed normal to the configured-for plane of translational movement.
